(19) United States
(12) Patent Application Publication
(10) Pub. No.: US 2026/0308448 A1
(43) Pub. Date: Oct. 8, 2026

(54) COMPOSITION EXHIBITING NARROW PHOTOLUMINESCENCE LINE WIDTH

(71) Applicant: UbiQD, Inc., Los Alamos, NM (US)

(72) Inventors: Hunter MCDANIEL, Los Alamos, NM (US); Nikolay S. MAKAROV, Los Alamos, NM (US); Karthik RAMASAMY, White Rock, NM (US); Riley KELEHAN, Los Alamos, NM (US); Ronald CICHOCKI, Santa Fe, NM (US)

(21) Appl. No.: 19/485,157

(22) PCT Filed: May 24, 2024
(86) PCT No.: PCT/US2024/031060

§ 371 Date: Nov. 17, 2025

Related U.S. Application Data
(60) Provisional application No. 63/504,044, filed on May 24, 2023.

(51) Int. Cl. C09K 11/88; B82Y 20/00; B82Y 40/00; C01B 19/00; C08J 5/18; C08K 3/30; C08K 9/02; C09K 11/02

(52) U.S. Cl. CPC C09K 11/883; C01B 19/002; C08J 5/18; C08K 3/30; C08K 9/02; C09K 11/02; C09K 11/881; B82Y 20/00; B82Y 40/00; C01P 2002/50; C01P 2002/72; C01P 2004/64; C01P 2006/60; C08J 2323/00; C08J 2323/08; C08J 2333/08; C08J 2353/02; C08K 2003/3036; C08K 2201/011

(57) ABSTRACT

A semiconductor quantum dot composition exhibiting narrow photoluminescence line width and/or faster PL decay.

### FIELD OF THE DISCLOSURE

The present invention is directed to compositions exhibiting a narrow photoluminescence (PL) line width and/or faster PL decay.

### BACKGROUND OF THE DISCLOSURE

Semiconductor quantum dots have attracted significant interest in various applications because of their excellent optical and electronic properties.

### SUMMARY OF THE DISCLOSURE

One aspect of the invention involves a composition AgInSeₓS₂₋ₓ having an emission spectrum with a full width half maximum (FWHM) of less than about 0.20 eV and a peak photoluminescence wavelength in the range of 750 nm to 950 nm.

Another aspect of the invention involves a composition CuInSeₓS₂₋ₓ having an emission spectrum with a full width half maximum (FWHM) of less than about 0.20 eV and a peak photoluminescence wavelength in the range of 750 to 950 nm.

Yet, another aspect of the invention involves a composition Cu_{y}Ag_{1-y}InSeₓS₂₋ₓ having an emission spectrum with a full width half maximum (FWHM) of less than about 0.20 eV and a peak photoluminescence wavelength in the range of 750 to 950 nm.

### BRIEF DESCRIPTION OF THE DRAWINGS

FIG. 1 shows a graph of (a) photoluminescence (PL) peak position (b) full width at half maximum (FWHM) from Cu_{y}Ag_{1-y}InSeₓS₂₋ₓ core quantum dots (QDs) as the copper to silver ratio in the quantum dot was varied.

FIG. 2 shows a graph of (a) photoluminescence (PL) peak position (b) full width at half maximum (FWHM) from AgInSeₓS₂₋ₓ core QDs as the silver to indium ratio in the quantum dot was varied.

FIG. 3 shows a graph of (a) photoluminescence (PL) peak position (b) full width at half maximum (FWHM) from AgInSeₓS₂₋ₓ core QDs as the selenium to silver and indium ratio in the quantum dot was varied.

FIG. 4 shows a graph of (a) photoluminescence (PL) peak position (b) full width at half maximum (FWHM) from CuInSeₓS₂₋ₓ core QDs as the copper to indium ratio in the quantum dot was varied.

FIG. 5 shows a graph of (a) photoluminescence (PL) peak position (b) full width at half maximum (FWHM) from CuInSeₓS₂₋ₓ core QDs as the selenium to copper and indium ratio in the quantum dot was varied.

FIG. 6 shows a graph of photoluminescence (PL) peak position and full width at half maximum (FWHM) from CuInSeₓS₂₋ₓ core QDs as the reaction time was varied for preparation of the quantum dot.

FIG. 7 shows the photoluminescence (PL) spectra of Cu_{y}Ag_{1-y}InSeₓS₂₋ₓ QDs showing variable full width at half maximum (FWHM).

FIG. 8 shows X-ray diffraction (XRD) patterns of AgInSeₓS₂₋ₓ QDs illustrating an orthorhombic crystal structure.

FIG. 9 shows the absorption and photoluminescence spectrum of AgInSeₓS₂₋ₓ QDs. The dashed line represents the second derivative of the absorption spectrum, indicating the presence of band-edge states close the photoluminescence (PL) peak position, suggesting the presence of a higher density of states and direct conduction band to valence band recombination.

FIG. 10 provides a graph showing photoluminescence (PL) decays and average lifetimes of the I-III-VI QDs of various compositions with photoluminescence (PL) peak position in the range of 800-900 nm.

FIG. 11 shows the absorption and photoluminescence spectrum of AgInSeₓS₂₋ₓ QDs. The dashed line represents the second derivative of the absorption spectrum, indicating the presence of band-edge states close the photoluminescence (PL) peak position, suggesting the presence of a higher density of states and direct conduction band to valence band recombination.

### DEFINITIONS AND ABBREVIATIONS

The following explanations of terms and abbreviations are provided to better describe the present disclosure and to guide those of ordinary skill in the art in the practice of systems, methodologies and compositions disclosed herein.

As used herein, “comprising” means “including,” and the singular form “a” or “an” or “the” include plural references unless the context clearly indicates otherwise. Unless the context clearly indicates otherwise, the term “or” is inclusive, and thus refers to both a single element of stated alternative elements and a combination of two or more of those elements.

Unless explained otherwise, all technical and scientific terms used herein have the same meaning as commonly understood to one or ordinary skill in the art to which this disclosure relates. Suitable methods and compositions are described herein for the practice or testing of the systems, methodologies and compositions described herein. However, it is to be understood that other methods and materials similar, or equivalent to, those described herein may be used in the practice or testing of these systems, methodologies and compositions disclosed herein. Consequently, the systems, methodologies, compositions, and examples disclosed herein are illustrative only, and are not intended to be limiting. Other features of the present disclosure will be apparent to those skilled in the art from the following detailed description and the appended claims. Unless otherwise indicated, all numbers expressing quantities of components, percentages, temperatures, times, and so forth as used in the specification or claims are to be understood as being modified by the term “about.” Unless otherwise indicated, non-numerical properties such as colloidal, continuous, crystalline, and so forth as used in the specification or claims are to be understood as being modified by the term “substantially,” meaning to a great extent or degree. Accordingly, unless otherwise indicated implicitly or explicitly, the numerical parameter and/or non-numerical properties set forth herein are approximations, and the optimal values of these properties and parameters may depend on the desired properties sought, the limits of detection under standard test conditions or methods, the limitations of the processing methods, and/or the nature of the property or parameter. When directly and explicitly distinguishing embodiments from disclosed prior art, the embodiment numbers are not approximations unless the word “about” is recited.
Emission spectrum: Those portions of the electromagnetic spectrum over which QDs (or a composition containing them) exhibit PL (in response to excitation by a light source) whose amplitude is at least 1% of the peak PL emission.
Nanoparticle: A nanoscale particle of a solid material. The nanoparticles disclosed herein are preferably crystalline and have a size of less than 500 nanometers in dimension. The nanoparticles disclosed herein may form a colloidal suspension. Embodiments of the disclosed nanoparticles may be of a single material or may include an inner core and an outer shell of differing materials. The nanoparticles may further include a plurality of ligands bound to the nanoparticle outer surface. Exemplary nanoparticles which may be utilized in the compositions, systems and methodologies described herein may comprise metals, metal oxides, metal chalcogenides, semiconductors, and insulators.
Photoluminescence (PL): The emission of light (electromagnetic radiation, in the form of photons) after the absorption of light. It is one form of luminescence (light emission) and is initiated by photoexcitation (excitation by photons).
Quantum Dots: A nanoparticle that exhibits size dependent electronic and optical properties due to quantum confinement. The quantum dots disclosed herein preferably have at least one dimension less than about 50 nanometers. The disclosed quantum dots may be colloidal quantum dots. Some of the quantum dots which may be utilized in the compositions, systems and methodologies described herein are made from a binary semiconductor material having a formula MX where M is a metal and X is typically selected from sulfur, selenium, tellurium, nitrogen, phosphorus, arsenic, antimony, or mixtures thereof. Exemplary binary quantum dots which may be used in the compositions, systems and methodologies described herein include CdS, CdSe, CdTe, PbS, PbSe, PbTe, ZnS, ZnSe, ZnTe, InP, InAs, Cu₂S, and In₂S₃. Other quantum dots which may be utilized in the compositions, systems and methodologies described herein are ternary, quaternary, and/or alloyed quantum dots including, but not limited to, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdSeₓS₂₋ₓ, ZnCdSeₓTe₂₋ₓ, ZnHgSeₓTe₂₋ₓ, ZnHgSeₓS₂₋ₓ, CdHgSeₓS₂₋ₓ, CdHgSeTe, CuInS₂, CuInSe₂, CuInGaSe₂, CuInZnS₂, CuZnSnSe₂, CuInSeₓS₂₋ₓ, CuInZnSeₓS₂₋ₓ, (Cu_{y}Ag_{1-y})InSeₓS₂₋ₓ, AgGaSeₓS₂₋ₓ, AgGa_{y}In_{1-y}SeₓS₂₋ₓ, CuGaSeₓS₂₋ₓ, CuGa_{y}In_{1-y}SeₓS₂₋ₓ, AgInS₂, AgInSe₂, and AgInSeₓS₂₋ₓ quantum dots, although the use of non-toxic quantum dots may be preferred for some uses or applications. Embodiments of the disclosed quantum dots may be of a single material or may include an inner core and an outer shell of differing materials. The inner core may also employ blends of the described materials for the quantum dot and/or the core. The outer shell may be a thin shell or layer formed by any suitable method, such as cation exchange. The outer shell materials can be composed of various I-III-VI semiconductor materials or II-VI semiconductor materials including blends thereof. The quantum dots may further include a plurality of ligands bound to the quantum dot surface.

### DETAILED DESCRIPTION

The present invention is directed to developing semiconductor nanocrystal compositions characterized as having narrow emissions. Such narrow emissions may also be controlled across a broad range of wavelengths. Our research has found that in some instances obtaining narrow emissions can result from selected control of cation and anion variation. In other instances, it has been found that increasing the overall particle size may also result in a narrowed photoluminescence (PL) full width half maximum (FWHM) emission.

In some instances, these materials can behave like phosphors in that they have mid-gap states involved in the photoluminescence (PL). This can lead to large Stokes shifts, longer PL lifetimes, and better stability.

Surprisingly, it has been found that by substitution of silver for copper, the material then behaves less like a phosphor and more like a typical quantum dot. The silver-indium-selenium composition has narrow emissions never previously found in the range of 750 nm to 950 nm, especially 800 to 900 nm by any known materials.

The peak position of the narrow PL emission can range from wavelengths of from 400 nm to 1400 nm. Depending on the application, the desired peak position can vary significantly. Peak positions in the range of about 750 nm to 950 nm, especially 800 nm to 900 nm can be desirable for applications such as NIR light conversion, NIR sensors while peak positions in the range of from 400 nm to 650 nm for display may be desirable for applications such as security ink authentication, displays, agriculture, and solar energy.

Control of the Cu/In ratio in the CuInSeₓS₂₋ₓ showed variation in both the peak position in wavelength maximum and the narrowing width of the FWHM. A much narrower emission was obtained at a Cu/In ratio of from about 0.4 to 0.7, with the narrowest emissions at Cu/In ratios of from about 0.45 to 0.65. The wavelength maximum at Cu/In ratios of 0.45 to 0.55 was found in the range of about 880 nm to 900 nm.

Another approach to obtaining desired narrow emissions is by selection of the anion and cation and the ratio of the particular anion to the combined cations. For example, a desired narrow emission resulted from a Se/Cu+In ratio of from about 1.0 to 1.4 whereby a narrowed photoluminescence (PL) full width half maximum (FWHM) emission of less than about 0.21 eV, about 0.19 eV at a Se/Cu+In ratio of about 1.2, all at a wavelength maximum in the range of about 850 nm to 990 nm.

Another approach to obtaining desired narrow emissions is by a mixture of cations, e.g., a blend of Ag and Cu. In studying the impact of the Ag:Cu ratio, it was found that compositions higher in Ag content yielded the narrowest emissions with a narrowed photoluminescence (PL) full width half maximum (FWHM) emission of less than about 0.14 eV at ratios of Ag:Cu of from about 0.8 to 1.0, with wavelength maximums trending to lower values as the Ag:Cu ratio increased, e.g., from about 880 to 920 nm for Ag:Cu ratios of from about 0.8 to 1.0.

Control of the Ag/In ratio in the AgInSeₓS₂₋ₓ showed variation in both the peak position in wavelength maximum and the narrowing width of the FWHM. A much narrower emission was obtained at an Ag/In ratio of from about 0.4 to 0.6, with the narrowest emissions at Ag/In ratios of from about 0.4 to 0.5. The wavelength maximum at Ag/In ratios of 0.4 to 0.5 was found in the range of about 830 nm to 950 nm.

Another approach involved varying the ratio of Se to a combination of Ag and In. Ratios of Se/(Ag+In) from about 1.1 to 2.0 yielded the narrowest emissions with a narrowed photoluminescence (PL) full width half maximum (FWHM) emission of about 0.1 eV, while wavelength maximums for Se/(Ag+In) ratios of 1.1 to 2,0 were generally found in the range of about 830 nm to 950 nm.

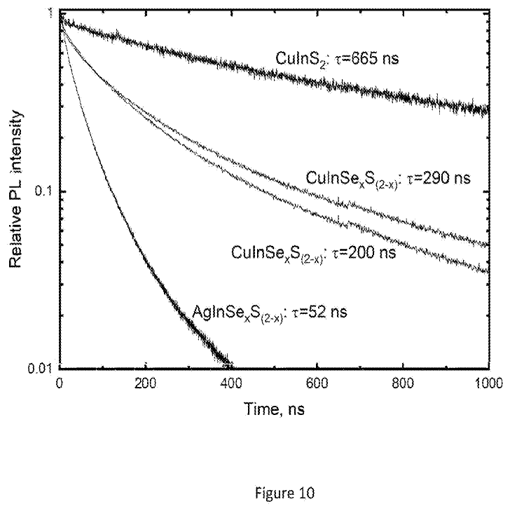

The PL lifetimes of the narrow-linewidth QDs vary in a wide range, anywhere between tens of nanoseconds to several hundreds of nanoseconds (See FIG. 10). Still, majority of the PL decays t are characterized by several exponential components with the longest lifetimes on the order of 1300 ns, and the shortest component on the order of 10-20 ns. Surprisingly, the narrowest emissions correlated with faster PL decay, typically less than 200 ns on average. The contribution (amplitude) of faster component lifetimes is more pronounced for narrower linewidth QDs, which might be partially attributed to their lower photoluminescence quantum yields (PLQY), and also partially to their narrower linewidth.

### EXAMPLES

The following examples are non-limiting and are merely intended to further illustrate the compositions, systems and methodologies described herein.

### Example 1

Synthesis of Narrow Line Width AgInSeₓS₂₋ₓ Core QDs

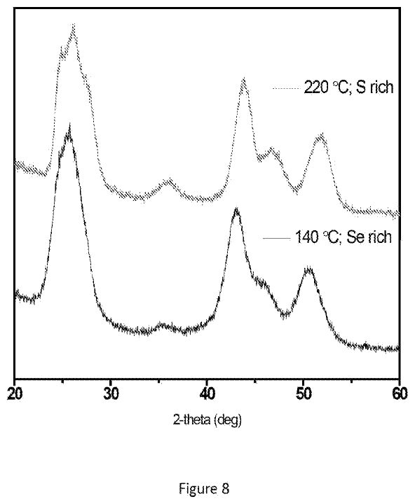

In a three-neck flask, indium acetate (1-6 mmol) and silver acetate (1-6 mmol) were added along with octadecene, dodecanethiol, and oleylamine. Separately, a selenium solution was prepared by dissolving metallic selenium (0-20 mmol) in oleylamine and dodecanethiol and injected into the indium flask temperature from 20° C. to 250° C. (See a representative XRD in FIG. 8.). The reaction was held at from 130° C. to 250° C. for from about 5 to 300 minutes or longer.

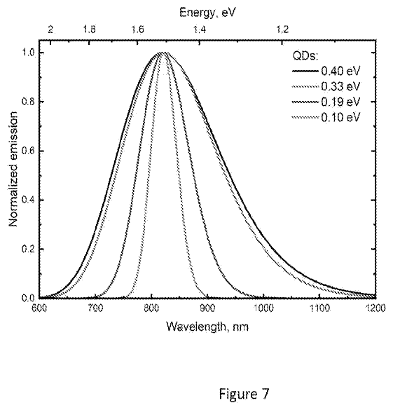

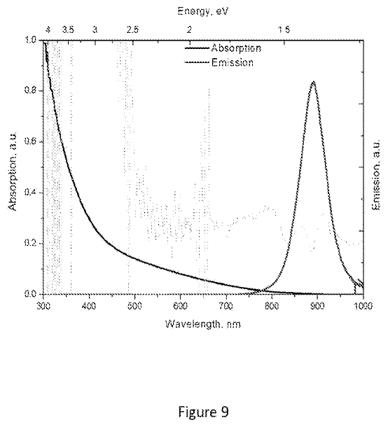

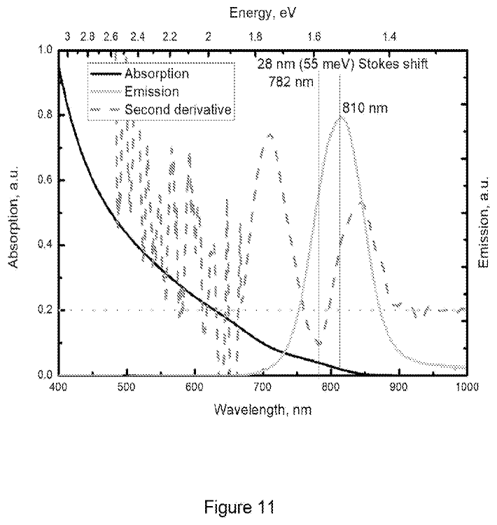

These reactions produce QDs having AgInSeₓS₂₋ₓ cores, where 0≤x≤2, with emissions at from 780 to 900nm with narrow PL linewidths as narrow as about 0.087 eV (see FIG. 7 and FIG. 9). Moreover, these QDs appear to have more band-to-band recombination, owing to the higher density of states near the band-edge and correlation between the second derivative of the absorption spectrum with the PL peak position (see FIG. 9 and FIG. 11). These QDs have average PL lifetimes of less than 200 ns, or even less than 100 ns (see FIG. 10).

### Example 2

Synthesis of Narrow Line Width Cu_{y}Ag_{1-y}InSeₓS₂₋ₓ Core QDs

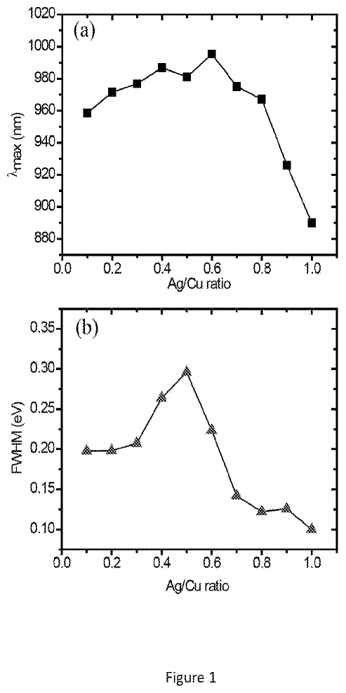

This example was conducted similar to example 1, with a series of different runs varying the copper to silver ratio from 0 to 1. The results from those various runs are shown in FIG. 1.

These reactions produce QDs having Cu_{y}Ag_{1-y}InSeₓS₂₋ₓ cores, where 0≤x≤2 and 0≤y≤1, with emissions at from 890 to 1000 nm with PL linewidths as narrow as 0.100 eV FWHM.

### Example 3

Synthesis of Narrow Line Width AgInSeₓS₂₋ₓ Core QDs

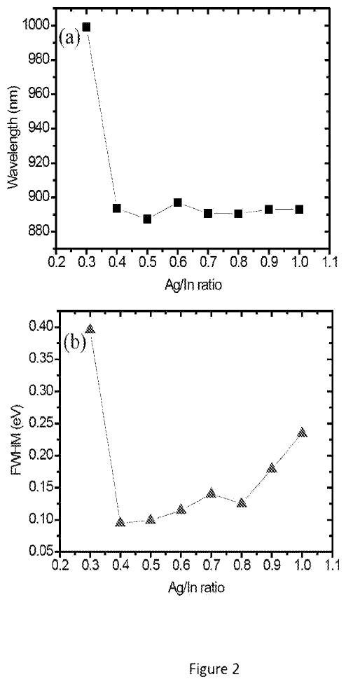

This example was conducted similar to example 1, with a series of different runs varying the silver to indium ratio from 0.2 to 1. These reactions produce QDs having AgInSeₓS₂₋ₓ cores, where 0≤x≤2. The results from those various runs are shown in FIG. 2.

### Example 4

Synthesis of Narrow Line Width AgInSeₓS₂₋ₓ Core QDs

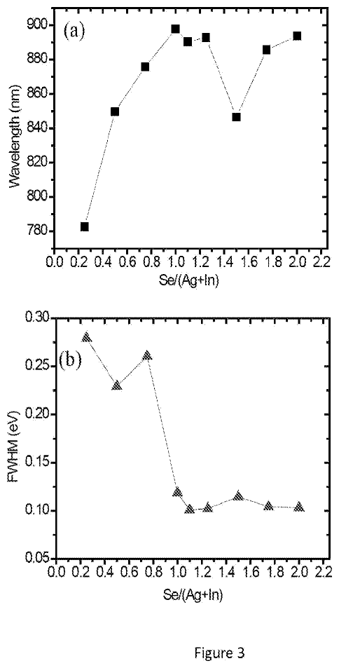

This example was conducted similar to example 1, with a series of different runs varying the selenium to silver and indium ratio from 0.2 to 2. These reactions produce QDs having AgInSeₓS₂₋ₓ cores, where 0≤x≤2. The results from those various runs are shown in FIG. 3.

### Example 5

Synthesis of Narrow Line Width CuInSeₓS₂₋ₓ Core QDs

In a three-neck flask, indium acetate (1-4 mmol), and copper iodide (1-4mmol) were added along with octadecene, dodecanethiol, and oleylamine. Separately, a selenium solution was prepared by dissolving metallic selenium (1-4 mmol) in oleylamine and dodecanethiol and injected into the indium flask temperature from 60° C. to 250° C. The reaction was held at from 130° C. to 250° C. for about 1-60 minutes or longer.

This reaction produced QDs having CuInSeₓS₂₋ₓ cores, where 0≤x≤2, emitting at 996 nm with PL line width of 0.17 eV FWHM. These QDs have average PL lifetimes of less than 300 ns, sometimes even around 200 ns (see FIG. 10).

### Example 6

Synthesis of Narrow Line Width CuInSeₓS₂₋ₓ Core Qds

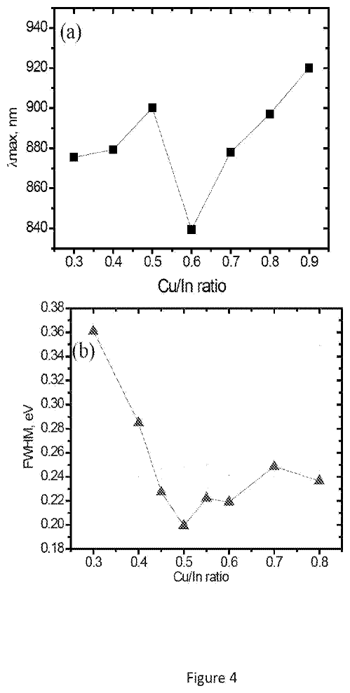

This example was conducted similar to example 5, with a series of different runs varying the copper to indium ratio from 0.2 to 0.8. These reactions produced QDs having CuInSeₓS₂₋ₓ cores, where 0≤x≤2. The results from those various runs are shown in FIG. 4.

### Example 7

Synthesis of Narrow Line Width CuInSeₓS₂₋ₓ Core QDs

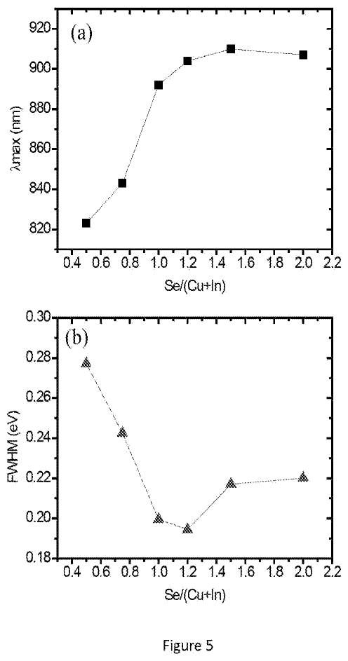

This example was conducted similar to example 5, with a series of different runs varying the selenium to copper and indium ratio from 0.2 to 2.0. These reactions produced QDs having CuInSeₓS₂₋ₓ cores, where 0≤x≤2.The results from those various runs are shown in FIG. 5.

### Example 8

Synthesis of Narrow Line Width CuInSeₓS₂₋ₓ Core QDs

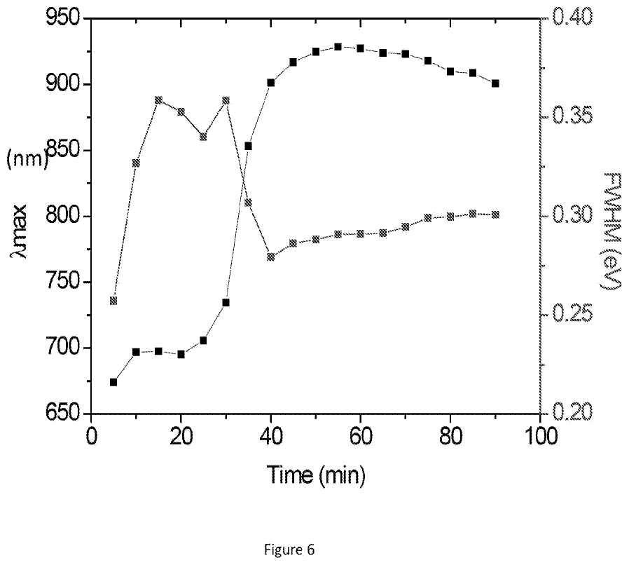

This example was conducted similar to example 5 with a series of different runs varying the reaction time. These reactions produced QDs having CuInSeₓS₂₋ₓ cores, where 0≤x≤2. The results from those various runs are shown in FIG. 6.

### Example 9

Synthesis of Narrow Line Width AgAlSeₓS₂₋ₓ Core QDs

In a three-neck flask, aluminum acetate (1-4 mmol) and silver acetate (1-4mmol) are added along with octadecene, dodecanethiol, and oleylamine. Separately, a selenium solution is prepared by dissolving metallic selenium (1-4 mmol) in oleylamine and dodecanethiol and injected into the indium flask temperature from 60° C. to 250° C. The reaction is held at from 130° C. to 250° C. for from about 1 to 60 minutes or longer. These reactions produced QDs having AgAlSeₓS₂₋ₓ cores, where 0≤x≤2.

### Example 10

Synthesis of Narrow Line Width AgIn_{y}Ga_{1-y}SeₓS₂₋ₓ Core QDs

In a three-neck flask, gallium acetate (1-4 mmol), indium acetate (1-4 mmol), and silver acetate (1-4mmol) are added along with octadecene, dodecanethiol, and oleylamine. Separately, a selenium solution is prepared by dissolving metallic selenium (0-20 mmol) in oleylamine and dodecanethiol and injected into the indium flask temperature from 60° C. to 250° C. The reaction is held at from 130° C. to 250° C. for from about 1 to 60 minutes or longer. These reactions produced QDs having AgIn_{y}Ga_{1-y}SeₓS₂₋ₓ cores, where 0≤x≤2 and 0≤y≤1

### Example 11

Synthesis of Narrow Line Width CuAlSeₓS₂₋ₓ Core QDs

In a three-neck flask, aluminum acetate (1-4 mmol) and copper iodide (1-4 mmol) are added along with octadecene, dodecanethiol, and oleylamine. Separately, a selenium solution is prepared by dissolving metallic selenium (1-4 mmol) in oleylamine and dodecanethiol and injected into the indium flask temperature from 60° C. to 250° C. The reaction was held at from 130° C. to 250° C. for from about 1 to 60 minutes or longer. These reactions produced QDs having CuAlSeₓS₂₋ₓ cores, where 0≤x≤2.

### Example 12

Synthesis of Narrow Line Width CuGaSeₓS₂₋ₓ Core QDs

In a three-neck flask, gallium acetate (1-4 mmol) and copper iodide (1-4mmol) are added along with octadecene, dodecanethiol, and oleylamine. Separately, a selenium solution is prepared by dissolving metallic selenium (1-4 mmol) in oleylamine and dodecanethiol and injected into the indium flask temperature from 60° C. to 250° C. The reaction was held at from 130° C. to 250° C. for from about 1 to 60 minutes or longer. These reactions produced QDs having CuGaSeₓS₂₋ₓ cores, where 0≤x≤2.

### Example 13

### ZnS Shell on Narrow Line Width Core QDs

Core solution from examples 1-12 was mixed with octadecene and dodecanethiol and zinc oleate heated from 130° C. to 300° C. and maintained for about 5 minutes to 12 hours or longer. The mixture was cooled to 25° C. for isolation.

The addition of a shell increased the PLQY to above 70%, and sometimes greater than 80%, or even above 90%. These core/shell QDs have increased average PL lifetimes of less than 700 ns, and sometimes less than 200 ns.

### Example 14

### CdS Shell on Narrow Line Width Core QDs

Core solution from examples 1-12 is mixed with octadecene and dodecanethiol and cadmium oleate heated from 130° C. to 300° C. and maintained for about 5 minutes to 12 hours or longer. The mixture is cooled to 25° C. for isolation.

The addition of a shell increases the PLQY to above 70%, and sometimes greater than 80%, or even above 90%. These core/shell QDs have increased average PL lifetimes of less than 500 ns, and sometimes less than 200 ns.

### Example 15

### CdSe Shell on Narrow Line Width Core QDs

Core solution from examples 1-12 is initially mixed with octadecene, cadmium oleate and selenium dissolved either in: a) trioctylphosphine; b) oleylamine and dodecanethiol; or c) oleic acid, and is then heated from about 130° C. to about 300° C. and maintained for from about 5 minutes to about 12 hours or longer as desired. The mixture is cooled to about 25° C. for isolation. The resultant shell is CdSe.

The addition of a shell increases the PLQY to above 70%, and sometimes greater than 80%, or even above 90%. These core/shell QDs have increased average PL lifetimes of less than 500 ns, and sometimes less than 200 ns.

### Example 16

ZnSeₓS₁₋ₓ Shell on Narrow Line Width Core QDs

Core solution from examples 1-12 is initially mixed with octadecene, dodecanethiol, zinc oleate and selenium dissolved either in: a) trioctylphosphine; b) oleylamine and dodecanethiol; or c) oleic acid, and is then heated from about 130° C. to about 300° C. and maintained for from about 5 minutes to about 12 hours or longer as desired. The mixture is cooled to about 25° C. for isolation. The resultant shell is ZnSeₓS₁₋ₓ, where 0≤x≤1.

The addition of a shell increases the PLQY to above 70%, and sometimes greater than 80%, or even above 90%. These core/shell QDs have increased average PL lifetimes of less than 700 ns, and sometimes less than 200 ns.

### Example 17

ZnₓCd₁₋ₓS Shell on Narrow Line Width Core QDs

Core solution from examples 1-12 is mixed with octadecene, dodecanethiol, zinc oleate and cadmium oleate heated from 130° C. to 300° C. and maintained for about 5 minutes to 12 hours or longer. The mixture is cooled to 25° C. for isolation. The resultant shell is ZnₓCd₁₋ₓS, where 0≤x≤1.

The addition of a shell increases the PLQY to above 70%, and sometimes greater than 80%, or even above 90%. These core/shell QDs have increased average PL lifetimes of less than 700 ns, and sometimes less than 200 ns.

### Example 18

### Wet-lamination of Narrow Linewidth QDs in Plastics

In a flask, QDs from example 1-16 are mixed with isobornyl acrylate monomer, styrene-b-ethylene-butadiene-styrene, butyl acrylate and omnirad 4265 at room temperature. The resulting mixture was coated between two sheets of barrier films of metallized polyethylene terephthalate (PET) using a drawdown coater and then photocured using 320-390 nm UV-light for the preparation of laminated films.

The laminated films are expected to show PL emission with FWHM from 0.09 eV to 0.35eV, and 0.01 to 0.03 eV narrower FWHM than that of the QDs alone (in dilute solvent rather than polymer). The polymer can help protect the QDs and increases the PLQY to above 70%, and sometimes greater than 80%, or even above 90%. These composites have average PL lifetimes of less than 500 ns, and sometimes less than 200 ns.

### Example 19

### Extrusion of Narrow Linewidth QDs in Polyolefin

In an extruder, polyolefin (POE) pellets were mixed with QDs from examples 1-16 at a feed rate of 220 grams per hour was introduced through the hopper at temperature from 130° C. to 220° C. and the resultant strands were chopped to produce pellets of blended material. The pellets were hot pressed to form about 50-100 μm thick films for optical characterization.

The linewidth of the resulting composite was 0.01 to 0.03 eV narrower FWHM than that of the QDs alone (in dilute solvent rather than polymer). The polymer can help protect the QDs and increases the PLQY to above 70%, and sometimes greater than 80%, or even above 90%. These composites have average PL lifetimes of less than 500 ns, and sometimes less than 200 ns.

### Example 20

### Extrusion of Narrow Linewidth QDs in Ethylene Vinylacetate

In an extruder, ethylene vinylacetate (EVA) pellets is mixed with QDs from examples 1-16 at a feed rate of 250 grams per hour was introduced through the hopper at temperature from 130° C. to 220° C. and the resultant strands were chopped to produce pellets of blended material. The pellets were hot pressed to form about 50-100 μm thick films for optical characterization.

The linewidth of the resulting composite was 0.01 to 0.03 eV narrower FWHM than that of the QDs alone (in dilute solvent rather than polymer). The polymer can help protect the QDs and increases the PLQY to above 70%, and sometimes greater than 80%, or even above 90%. These composites have average PL lifetimes of less than 500 ns, and sometimes less than 200 ns.

### Example 21

Narrow Densities of States in Cu_{y}Ag_{1-y}InSeₓS₂₋ₓ Semiconductor Nanocrystals

Semiconductor nanocrystrals emit photons as a pathway for excited state recombination where an excited electron recombines with a hole (electron vacancy). Typically, in a semiconductor the excited state electron has moved from the valence band up to the conduction band, but this can be modified in CuInSeₓS₂₋ₓ nanocrystals or quantum dots by the presence of mid-gap states. Such excited states form when a photon interacts with a mid-gap state or valence band electron. These materials may have a mid-gap state that contributes an electron to the valence band enabling the conduction band to provide a photoexcited electron to the same mid-gap state with narrow range of energies, less than 300 meV in FWHM, preferably less than 200 meV, or potentially even less than 100 meV. In some cases the nanocrystals may not have any mid-gap states that participate in the recombination and instead the semiconductor nanocrystral having a composition of Cu_{y}Ag_{1-y}InSeₓS₂₋ₓ wherein 0≤x≤2 and 0≤y≤1 may have a distribution of lowest conduction band states and highest valence band states that together have with narrow range of transition energies less than 300 meV in FWHM, preferably less than 200 meV, or potentially even less than 100 meV. In any event the distribution of recombination states is relatively narrow, narrower than has been traditionally seen for CuInSeₓS₂₋ₓ nanocrystals or quantum dots. A narrow range of transition energies will manifest in various useful ways, including, but not limited to, narrow photoluminescence linewidth. Although the present invention has been described with reference to specific details, it is not intended that such details should be regarded as limitations upon the scope of the invention. Various modifications, substitutions, combinations, and ranges of parameters may be made or utilized in the compositions, and methodologies described herein.

1. A composition AgInSexS2-x having an emission spectrum with a full width half maximum (FWHM) of less than about 0.20 eV and a peak photoluminescence wavelength in the range of 750 nm to 950 nm, wherein 0≤x≤2.

2. The composition of claim 1 having an emission spectrum with a full width half maximum (FWHM) of less than about 0.10 eV.

3. The composition of claim 1, wherein a PL decay of the composition is less than about 200 ns.

4. The composition of claim 1, wherein a PL decay of the composition is less than 100 ns.

5. The composition of claim 1 possessing of crystal structure that exhibits photoluminescence emission FWHM <0.2 eV.

6. The composition of claim 1 partially or fully covered by second shell material.

7. A composition selected from the group consisting of CuInSexS2-x, AgInSexS2-x, and CuyAg1-yInSexS2-x having an emission spectrum with a full width half maximum (FWHM) of less than about 0.20 eV and a tunable peak photoluminescence wavelength in the range of 400 to 1400 nm, wherein 0≤x≤2 and 0≤y≤1.

8. The composition of claim 7 wherein the photoluminescence peak is at a wavelength from 750 to 950 nm.

9. A semiconductor nanocrystal containing at least silver or copper or both, in combination with indium having a mid-gap state that contributes an electron to the valence band enabling the conduction band to provide a photoexcited electron to the same mid-gap state with narrow range of energies, less than 300 meV in FWHM.

10. A polymer film containing a weight percentage between about 0.05% and 50% of quantum dots selected from the group consisting of CuInSexS2-x, AgInSexS2-x, and CuyAg1-yInSexS2-x having an emission spectrum with a full width half maximum (FWHM) of less than about 0.20 eV, the polymer film comprised of a polymer selected from the group consisting of polyolefin, ethylene vinyl acetate, polyethylene, polyurethane, polyvinyl butyral, ionomers, acrylic and thereof, wherein 0≤x≤2 and 0≤y≤1.

11. The polymer film of claim 10 wherein the quantum dots are of AgInSexS2-x having an emission spectrum with a full width half maximum (FWHM) of less than about 0.20 eV and a peak photoluminescence wavelength in the range of 750 nm to 950 nm, wherein 0≤x≤2.

12. A polymer film containing a percentage of quantum dots selected from the group consisting of CuInSexS2-x, AgInSexS2-x, and CuyAg1-yInSexS2-x having an emission spectrum with a full width half maximum (FWHM) of less than about 0.20 eV and a tunable peak photoluminescence wavelength in the range of 530 to 1400 nm, the polymer film comprised of a polymer selected from the group consisting of polyolefin, ethylene vinyl acetate, olyethylene, polyurethane, polyvinyl butyral, ionomers, acrylic and thereof, wherein 0≤x≤2 and 0≤y≤1.

13. The polymer film of claim 10 wherein the photoluminescence peak is at a wavelength from 750 to 950 nm.

14. A semiconductor nanocrystal having a mid-gap state that contributes an electron to the valence band enabling the conduction band to provide a photoexcited electron to the same mid-gap state with narrow range of energies, less than 300 meV in FWHM.

15. A semiconductor nanocrystal having a composition CuyAg1-yInSexS2-x wherein 0≤x≤2 and 0≤y≤1 and a distribution of lowest conduction band states and highest valence band states that together have with narrow range of transition energies less than 300 meV in FWHM.
